(19) United States
(12) Patent Application Publication
(10) Pub. No.: US 2026/0190874 A1
(43) Pub. Date: Jul. 2, 2026

(54) SERIES PHASE CHANGE MATERIAL SWITCHES WITH OFF-STATE VOLTAGE EQUALIZERS AND METHOD FOR FORMING THE SAME

(71) Applicant: Taiwan Semiconductor Manufacturing Company Limited, Hsinchu (TW)

(72) Inventors: Ching-En Chen, Chiayi City (TW); Kuo-Pin Chang, Zhubei City (TW); Hung-Ju Li, Hsinchu City (TW); Yu-Wei Ting, Taipei City (TW); Kuo-Ching Huang, Hsinchu City (TW)

(21) Appl. No.: 19/001,700

(22) Filed: Dec. 26, 2024

(51) Int. Cl. H10N 70/00; H10N 70/20

(52) U.S. Cl. CPC H10N 70/8613; H10N 70/023; H10N 70/026; H10N 70/063; H10N 70/231; H10N 70/8828; H10N 70/883; H10N 70/8833

(57) ABSTRACT

A device structure may be formed by: forming dielectric layers with metal interconnect structures formed therein on a substrate; forming at least one heater element over the dielectric layers, each of the at least one heater element including a strip portion, a first terminal portion, and a second terminal portion; forming at least one heater-cover plate stack including a electrically-insulating and thermally-conductive plate including a first material and a semiconducting plate including a second material having a lower electrical resistivity than the first material over a one of the at least one heater element; and depositing and patterning a phase change material layer over the at least one heater-cover plate stack.

### BACKGROUND

Phase change material (PCM) switches are utilized in radio-frequency (RF) applications for controlling signal flow by switching between high and low resistivity states. These switches are often used in stacked configurations to distribute voltage across multiple devices and improve power handling capabilities. An issue in existing stacked PCM RF switches occurs when the devices are in the OFF state. In this state, the off-state capacitance of each switch is smaller than the parasitic capacitance to the substrate, leading to an uneven distribution of voltage across the stacked switches. Additionally, variability in the off-state resistance among the switches further exacerbates the voltage imbalance, resulting in excessive voltage drops across certain switches, particularly the first one in the stack. This imbalance may lead to device breakdown and limits the overall power handling capability of the stacked configuration. The combined effects of off-state capacitance and off-state resistance variability present a challenge in maintaining reliable and consistent performance in high-power RF applications, where proper voltage distribution across all devices in the stack is critical to preventing failure under elevated power conditions.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-sectional view of an embodiment structure after formation of a semiconductor circuit, first metal interconnect structures, and first dielectric layers according to an embodiment of the present disclosure.

FIG. 2 is a vertical cross-sectional view of the embodiment structure after deposition of at least one metallic material layer according to an embodiment of the present disclosure.

FIG. 3A is a vertical cross-sectional view of the embodiment structure after patterning the at least one metallic material layer into metallic plates and a plurality of heater elements according to an embodiment of the present disclosure.

FIG. 3B is a top-down view of the embodiment structure of FIG. 3A. The vertical plane A-A′ is the cut plane of the vertical cross-sectional view of FIG. 3A.

FIG. 3C is a vertical cross-sectional view of the exemplary structure along the vertical plane C-C′ of FIG. 3B.

FIG. 4A is a vertical cross-sectional view of the embodiment structure after formation of an electrode-level dielectric layer according to an embodiment of the present disclosure.

FIG. 4B is a top-down view of the embodiment structure of FIG. 4A. The vertical plane A-A′ is the cut plane of the vertical cross-sectional view of FIG. 4A.

FIG. 4C is a vertical cross-sectional view of the exemplary structure along the vertical plane C-C′ of FIG. 4B.

FIG. 5 is a vertical cross-sectional view of the embodiment structure after formation of a layer stack including an electrically-insulating and thermally-conductive layer and a semiconducting material layer according to an embodiment of the present disclosure.

FIG. 6A is a vertical cross-sectional view of the embodiment structure after patterning the layer stack into a plurality of heater-cover plate stacks according to an embodiment of the present disclosure.

FIG. 6B is a top-down view of the embodiment structure of FIG. 6A. The vertical plane A-A′ is the cut plane of the vertical cross-sectional view of FIG. 6A. The vertical plane A-A′ is the cut plane of the vertical cross-sectional view of FIG. 6A.

FIG. 6C is a vertical cross-sectional view of the exemplary structure along the vertical plane C-C′ of FIG. 6B.

FIG. 7 is a vertical cross-sectional view of the embodiment structure after formation of a phase change material layer, a first cover dielectric layer, and a second cover dielectric layer according to an embodiment of the present disclosure.

FIG. 8A is a vertical cross-sectional view of the embodiment structure after patterning the second cover dielectric layer, the first cover dielectric layer, and the phase change material layer into a second cover dielectric plate, a first cover dielectric plate, and phase change material portions according to an embodiment of the present disclosure.

FIG. 8B is a top-down view of the embodiment structure of FIG. 8A. The vertical plane A-A′ is the cut plane of the vertical cross-sectional view of FIG. 8A. The vertical plane A-A′ is the cut plane of the vertical cross-sectional view of FIG. 8A.

FIG. 8C is a vertical cross-sectional view of the exemplary structure along the vertical plane C-C′ of FIG. 8B.

FIG. 9A is a vertical cross-sectional view of the embodiment structure after formation of second dielectric layers, metallic via structures, metal pad structures, and a radio-frequency antenna according to an embodiment of the present disclosure.

FIG. 9B is a top-down view of the embodiment structure of FIG. 9A. The vertical plane A-A′ is the cut plane of the vertical cross-sectional view of FIG. 9A. The vertical plane A-A′ is the cut plane of the vertical cross-sectional view of FIG. 9A.

FIG. 9C is a vertical cross-sectional view of the exemplary structure along the vertical plane C-C′ of FIG. 9B.

FIG. 10 is a vertical cross-sectional view of an alternative configuration of the embodiment structure after formation of second dielectric layers according to an embodiment of the present disclosure.

FIG. 11 is a circuit diagram of the series connection of PCM switches according to an embodiment of the present disclosure.

FIG. 12 is a first flowchart that illustrates general processing steps for manufacturing a device structure according to embodiments of the present disclosure.

FIG. 13 is a second flowchart that illustrates general processing steps for manufacturing a device structure according to embodiments of the present disclosure.

### DETAILED DESCRIPTION

The following disclosure provides many different embodiments, or examples, for implementing various features of the provided subject matter. Specific examples of components and arrangements are described below to simplify the present disclosure. These are merely examples, and are not limiting. Drawings are not drawn to scale. Elements with the same reference numerals refer to the same element, and are presumed to have the same material composition and the same thickness range unless expressly indicated otherwise. All features of an original embodiment are presumed to be present in any derived embodiment unless expressly disclosed otherwise. Thus, features described with reference to related embodiments in the drawings and/or in the specification provide support for features in an embodiment. Embodiments are expressly contemplated in which multiple instances of any described element are repeated unless expressly stated otherwise. Embodiments are expressly contemplated in which non-essential elements are omitted even if such embodiments are not expressly disclosed but are known in the art.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Various embodiments disclosed herein are directed to a series connection of phase change material (PCM) radio-frequency (RF) switches with off-state voltage equalizers and methods for forming the same. Embodiments of the present disclosure provide methods and device structures that address the challenges related to the uneven voltage distribution across stacked phase change material (PCM) switches in the off state, which is a common problem in radio-frequency (RF) applications. In instances in which PCM switches are stacked to improve power handling, the variability in off-state resistance and the effects of parasitic capacitance between the switches and the substrate may lead to voltage imbalances. This voltage imbalance may result in disproportionate voltage drops across certain switches in the stack, particularly the first switch, which may experience excessive voltage stress, causing device breakdown and limiting the overall power handling capacity of the device structure.

To mitigate the voltage imbalance problem in the off-state, embodiments of the present disclosure introduce off-state voltage equalizers that may be incorporated into a series of PCM switches. Each of the PCM RF switches may include a heater-cover plate stack, comprising an electrically-insulating and thermally-conductive plate made from a first material with high resistivity, and a semiconducting plate made from a second material with lower resistivity. This configuration enhances both thermal management and electrical resistivity balancing. The second material, selected from low-resistivity metal oxides or nitrides, ensures proper conductivity, while the first material, such as aluminum nitride or silicon nitride, provides insulation and efficient heat dissipation, thereby promoting even voltage distribution across the switches when they are in the off-state.

The off-state voltage equalizers of various embodiments of the present disclosure may comprise semiconducting plates having electrical resistivity greater than conductive materials, and may provide uniform voltage distribution in an off state across a series connection of PCM RF switches. This uniform voltage distribution improves the power handling capabilities of the switch series and reduces the risk of device failure due to excessive voltage drops. As a result, various embodiments disclosed herein provide reliable operation of RF switches in high-power applications, effectively addressing the voltage imbalance issues that have previously limited performance. The various aspects and embodiments of the methods and structures of the present disclosure are described with reference to accompanying drawings herebelow.

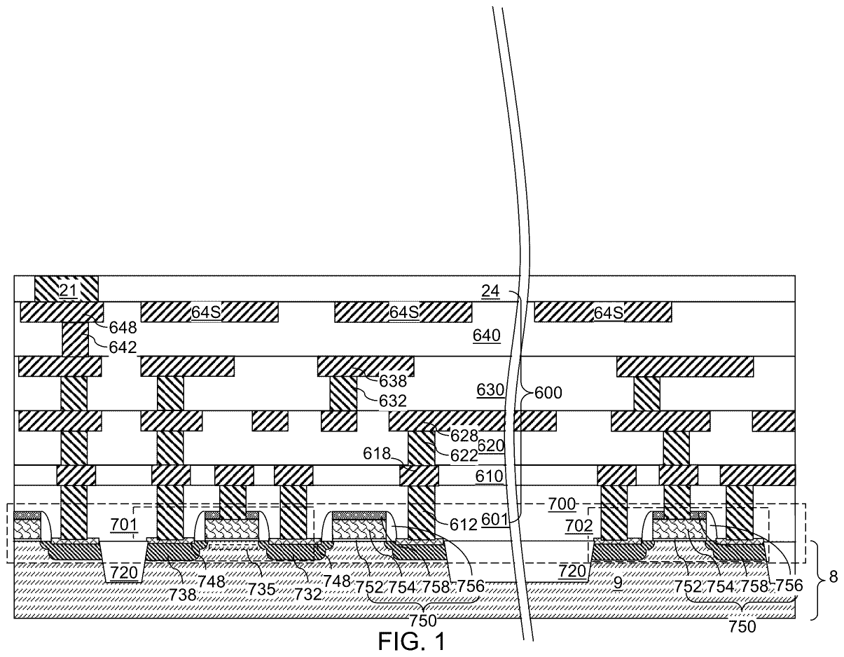

Referring to FIG. 1, an embodiment structure according to the present disclosure is illustrated. The embodiment structure includes a substrate 8, which may be a semiconductor substrate such as a commercially available silicon substrate. The substrate 8 may include a semiconductor material layer 9 at least at an upper portion thereof. The semiconductor material layer 9 may be a surface portion of a bulk semiconductor substrate, or may be a top semiconductor layer of a semiconductor-on-insulator (SOI) substrate. In one embodiment, the semiconductor material layer 9 includes a single crystalline semiconductor material such as single crystalline silicon. In one embodiment, the substrate 8 may include a single crystalline silicon substrate including a single crystalline silicon material.

Shallow trench isolation structures 720 including a dielectric material such as silicon oxide may be formed in an upper portion of the semiconductor material layer 9. Suitable doped semiconductor wells, such as p-type wells and n-type wells, may be formed within each area that is laterally enclosed by a portion of the shallow trench isolation structures 720. A semiconductor circuit 700 may be formed over the top surface of the semiconductor material layer 9. The semiconductor circuit 700 may comprise a complementary metal oxide semiconductor (CMOS) circuit including p-type field effect transistors and n-type field effect transistors. For example, each field effect transistor may include a source region 732, a drain region 738, a semiconductor channel 735 that includes a surface portion of the substrate 8 extending between the source region 732 and the drain region 738, and a gate structure 750. The semiconductor channel 735 may include a single crystalline semiconductor material. Each gate structure 750 may include a gate dielectric layer 752, a gate electrode 754, a gate cap dielectric 758, and a dielectric gate spacer 756. A source-side metal-semiconductor alloy region 74_1 may be formed on each source region 732, and a drain-side metal-semiconductor alloy region 748 may be formed on each drain region 738. The devices formed on the top surface of the semiconductor material layer 9 may include complementary metal-oxide-semiconductor (CMOS) transistors and optionally additional semiconductor devices (such as resistors, diodes, capacitor structures, etc.), and are collectively referred to as semiconductor circuit 700.

One or more of the field effect transistors in the semiconductor circuit 700 may include a semiconductor channel 735 that contains a portion of the semiconductor material layer 9 in the substrate 8. In embodiments in which the semiconductor material layer 9 includes a single crystalline semiconductor material such as single crystalline silicon, the semiconductor channel 735 of each field effect transistor in the semiconductor circuit 700 may include a single crystalline semiconductor channel such as a single crystalline silicon channel. In one embodiment, a subset of the field effect transistors in the semiconductor circuit 700 may include a node that is subsequently electrically connected to a node of an energy harvesting device and/or to a battery structure to be subsequently formed.

In one embodiment, the substrate 8 may include a single crystalline silicon substrate, and the field effect transistors may include a portion of the single crystalline silicon substrate as a semiconducting channel. As used herein, a “semiconducting” element refers to an element having electrical conductivity in the range from 1.0×10⁻⁶ S/cm to 1.0×10⁵ S/cm, which corresponds to electrical resistivity in the range from 1.0×10⁻⁵ Ohm·cm to 1.0×10⁶ Ohm·cm. As used herein, a “semiconductor material” refers to a material having electrical conductivity in the range from 1.0×10⁻⁶ S/cm to 1.0×10⁵ S/cm in the absence of electrical dopants therein, and is capable of producing a doped material having electrical conductivity in a range from 1.0 S/cm to 1.0×10⁵ S/cm upon suitable doping with an electrical dopant. As used herein, a “conductive” element refers to an element having electrical conductivity greater than 1.0×10⁵ S/cm, i.e., having electrical resistivity less than 1.0×10⁻⁵ Ohm·cm. As used herein, an “insulating” element refers to an element having electrical conductivity less than 1.0×10⁻⁶ S/cm, i.e., having electrical resistivity greater than 1.0×10⁶ Ohm·cm.

According to an aspect of the present disclosure, the semiconductor circuit 700 comprises a power amplifier 701 that generates a radio-frequency (RF) signal at a sufficient signal strength for transmitting to a radio-frequency antenna. As used herein, a “power amplifier” refers to an amplifier that increases the power of a signal. Typically, the power amplifier is used in transmission paths to drive the antenna with a high-power signal. For example, the power that is transmitted out of the output node of the power amplifier 701 may be in a range from 1 Watt to 100 Watts, although lesser and greater powers may be transmitted from the output node of the power amplifier 701. As used herein, a “radio-frequency (RF) signal” refers to an electromagnetic wave with a frequency within the range of about 3 kHz to 300 GHz, used for wireless communication. In one embodiment, the drain region 738 of the power amplifier 701 may comprise an output node of the power amplifier 701. Further, the semiconductor circuit comprises a low noise amplifier (LNA) 702 that is configured to receive a radio-frequency signal from the radio-frequency antenna. As used herein, a “low noise amplifier” refers to an amplifier that amplifies weak signals with minimal added noise. Typically, the LNA is used in the reception path to amplify the received signal before it is processed by subsequent stages. For example, the amplitude of a radio-frequency signal that is transmitted to the input node of the low noise amplifier may be in a range from 1 microvolt to 100 millivolts, although lesser and greater amplitudes may also be used. In one embodiment, the gate electrode of the LNA may serve as the input node.

Various first dielectric layers 600 having various first metal interconnect structures (612, 618, 622, 628, 632, 638, 642, 648, 21, 64S) formed therein may be subsequently formed over the substrate 8 and the semiconductor circuit 700. In an illustrative example, the first dielectric layers may include, for example, a contact-level dielectric layer 601 that surrounds contact structures providing electrical connection to the source regions 732, the drain regions 738, and the gate electrodes 754, a first interconnect-level dielectric layer 610, a second interconnect-level dielectric layer 620, a third interconnect-level dielectric layer 630, a fourth interconnect-level dielectric layer 640, and a via-level dielectric layer 24. The first metal interconnect structures may include device contact via structures 612 extending through the contact-level dielectric layer 601 and contacting a component of the semiconductor circuit 700, first metal line structures 618 formed in the first interconnect-level dielectric layer 610, first metal via structures 622 extending through a lower portion of the second interconnect-level dielectric layer 620, second metal line structures 628 formed in an upper portion of the second interconnect-level dielectric layer 620, second metal via structures 632 extending through a lower portion of the third interconnect-level dielectric layer 630, third metal line structures 638 formed in an upper portion of the third interconnect-level dielectric layer 630, third metal via structures 642 extending through a lower portion of the fourth interconnect-level dielectric layer 640, fourth metal line structures 648 formed in an upper portion of the fourth interconnect-level dielectric layer 640, connection via structures 21 extending through the via-level dielectric layer 24, and heat spreaders 64S that may be subsequently used to dissipate heat that is generated from heater elements of PCM switches to be subsequently formed. While the present disclosure is described using an embodiment in which four levels of metal line structures are formed in first dielectric layers, embodiments are expressly contemplated herein in which a lesser or greater number of levels of metal line structures are formed in the first dielectric layers.

Each of the first dielectric layers 600 may include a dielectric material such as undoped silicate glass, a doped silicate glass, organosilicate glass, amorphous fluorinated carbon, porous variants thereof, or combinations thereof. Each of the first metal interconnect structures (612, 618, 622, 628, 632, 638, 642, 648, 21, 64S) may include at least one conductive material, which may be a combination of a metallic liner (such as a metallic nitride or a metallic carbide) and a metallic fill material. Each metallic liner may include TiN, TaN, WN, TiC, TaC, and WC, and each metallic fill material portion may include W, Cu, Al, Co, Ru, Mo, Ta, Ti, alloys thereof, and/or combinations thereof. Other suitable metallic liner and metallic fill materials within the contemplated scope of disclosure may also be used. In one embodiment, the first metal via structures 622 and the second metal line structures 628 may be formed as integrated line and via structures by a dual damascene process. Generally, any contiguous set of a metal line structure (628, 638, 648) and at least one underlying metal via structure (622, 632, 642) may be formed as an integrated line and via structure.

Generally, semiconductor devices (such as field effect transistors) may be formed on a substrate 8, and first metal interconnect structures (612, 618, 622, 628, 632, 638, 642, 648, 21, 64S) and first dielectric layers 600 over the semiconductor devices (such as the field effect transistors). The first metal interconnect structures (612, 618, 622, 628, 632, 638, 642, 648, 21, 64S) may be formed in the first dielectric layers 600, and may be electrically connected to the semiconductor devices.

The connection via structures 21 may be located at positions over which metallic plates of phase change material (PCM) radio-frequency (RF) switching circuit are to be subsequently formed. The connection via structures 21 may comprise signal node connection via structures 21 that are used to contact a subset of the metallic plates that are used as signal nodes of the PCM RF switching circuit. The signal node connection via structures 21 may be used to contact a signal node of a first PCM switch of a series connection of PCM switches to be subsequently formed. The heat spreaders 64S may be formed underneath the level of the via-level dielectric layer 24 in areas in which strip portions of heater elements are to be subsequently formed. In an illustrative example, the heat spreaders 64S may be formed in a dielectric layer that directly underlies the via-level dielectric layer 24, such as the fourth interconnect-level dielectric layer 640.

Generally, a semiconductor circuit 700 may be formed on the substrate 8. The semiconductor circuit 700 may include a radio-frequency (RF) transistor circuit comprising a power amplifier 701 and/or a low noise amplifier 702. An electrical connection with one of the metallic plates to be subsequently formed may be provided through a subset of the first metal interconnect structures (612, 618, 622, 628, 632, 638, 642, 648, 21) that includes a connection via structure 21.

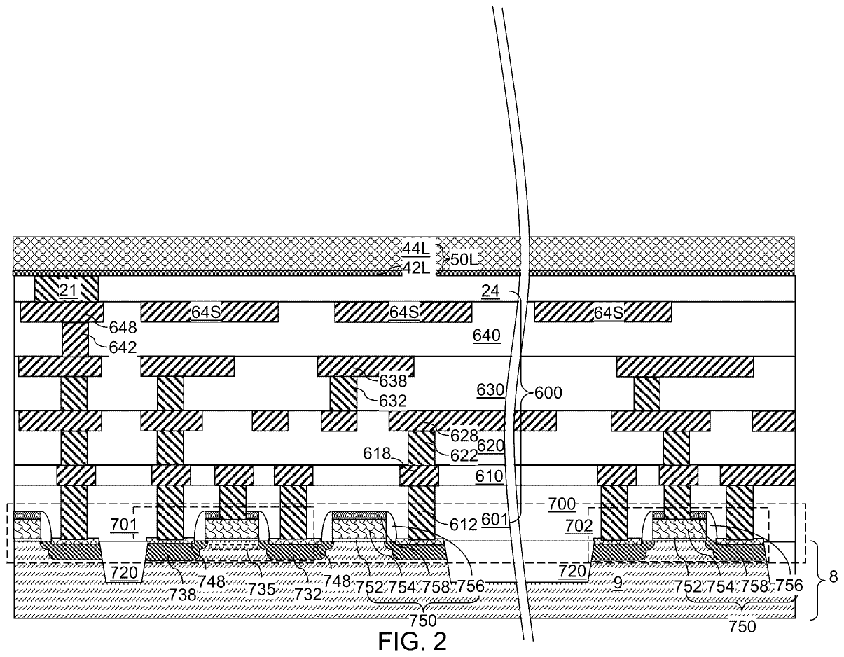

Referring to FIG. 2, at least one metallic material layer 50L may be deposited over the via-level dielectric layer 24. Generally, the at least one metallic material layer 50L may be deposited over the topmost surface of the first dielectric layers 600. In one embodiment, the at least one metallic material layer 50L comprises at least one metallic material that may withstand an elevated temperature that is sufficiently high to induce melting of a phase change material. Exemplary materials may include metals, metal-nitrides, metal-oxides, and doped-poly materials. For example, the metallic material may be selected from aluminum (Al), titanium (Ti), tantalum (Ta), gold (Au), platinum (Pt), tungsten (W), nickel (Ni), indium (In), molybdenum (Mo), ruthenium (Ru), zinc (Zn), iridium (Ir), aluminum nitride (AlN), titanium nitride (TiN), tantalum nitride (TaN), tungsten nitride (WN), iridium oxide (IrO₂), and doped polysilicon (e.g., n⁺ poly, p⁺ poly).

In one embodiment, the at least one metallic material layer 50L may comprise at least one metallic material that is selected from tungsten, tantalum, molybdenum, niobium, rhenium, tungsten nitride, tantalum nitride, titanium nitride, molybdenum nitride, copper, aluminum, gold, silver, platinum, and aluminum nitride. Additional materials may include nickel, iridium, ruthenium, and zinc, as well as metal-oxides such as iridium oxide (IrO₂). In one embodiment, the at least one metallic material layer 50L may comprise an optional metallic barrier material layer 42L and a main metallic layer 44L. The metallic barrier material layer 42L may consist essentially of a metallic nitride material that is selected from tungsten nitride, tantalum nitride, titanium nitride, and molybdenum nitride. The main metallic layer 44L may comprise a metal that is selected from tungsten, tantalum, molybdenum, niobium, rhenium, copper, aluminum, gold, silver, platinum, and aluminum nitride. In a non-limiting illustrative example, the at least one metallic material layer 50L may comprise a metallic barrier material layer 42L including titanium nitride having a melting point of 2,930 degrees Celsius, and a main metallic layer 44L including tungsten having a melting point of 3,412 degrees Celsius.

Generally, the at least one metallic material layer 50L may be deposited by physical vapor deposition (PVD) and/or chemical vapor deposition (CVD). Additional materials such as doped polysilicon (e.g., n⁺ poly, p⁺ poly) may be included to improve the material properties for specific applications. The thickness of the at least one metallic material layer 50L may be in a range from 30 nm to 300 nm, such as from 60 nm to 150 nm, although lesser and greater thicknesses may also be used.

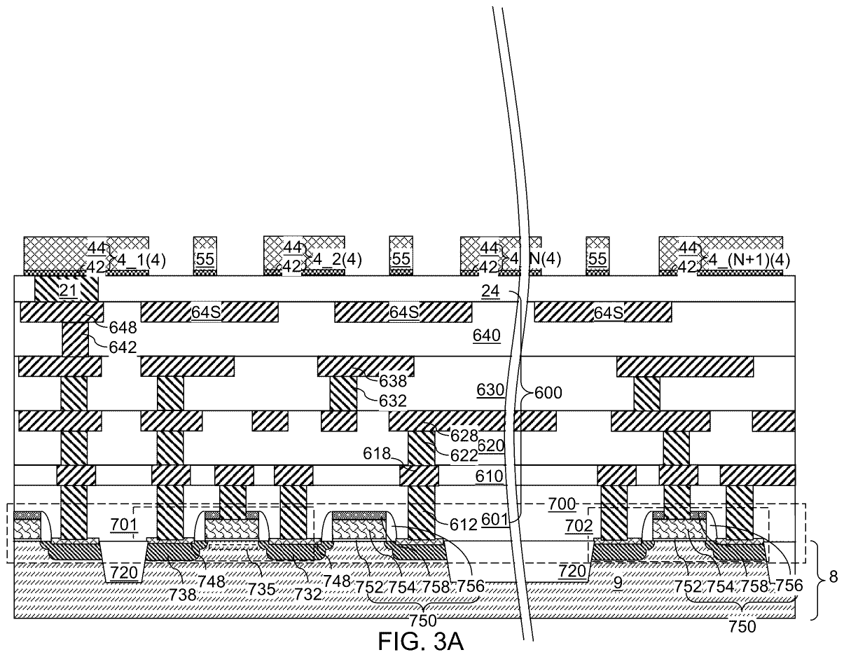

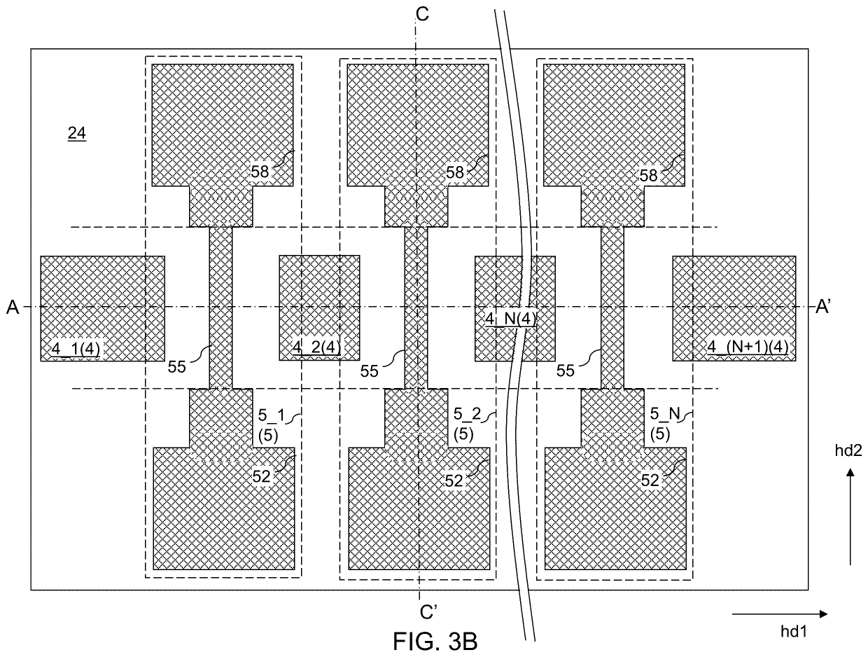

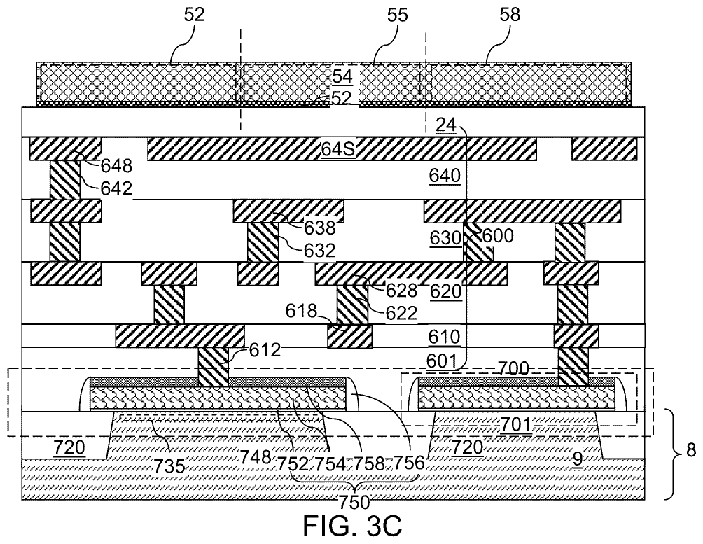

Referring to FIGS. 3A-3C, an etch mask layer (such as a patterned photoresist layer) may be applied over the at least one metallic material layer 50L, and may be lithographically patterned to form a patterned etch mask layer (not illustrated). An etch process (such as a reactive ion etch process) may be performed to transfer the pattern in the patterned etch mask layer through the at least one metallic material layer 50L. The pattern in the patterned etch mask layer may be selected such that patterned remaining portions of the at least one metallic material layer 50L comprises a laterally alternating sequence of (N+1) metallic plate patterns N heater element patterns. The number N is an integer greater than 0, and may be greater than 1. For example, the number N may have a value in a range from 1 to 20, such as from 2 to 6, although a greater value may also be used.

An anisotropic etch process may be performed to transfer the pattern in the etch mask layer though the at least one metallic material layer 50L. The at least one metallic material layer 50L may be patterned into a laterally alternating sequence of N+1) metallic plates 4 and N heater elements 5. The (N+1) metallic plates 4 may comprise, in a spatial order along a lateral direction that may, or may not, be straight, a first metallic plate 4_1, a second metallic plate 4_2, etc. up to an N-th metallic plate 4_N and an (N+1)-th metallic plate 4_(N+1). The N heater elements 5 may comprise a first heater element 5 located between the first metallic plate 4_1 and the second metallic plate 4_2, a second heater element 5 located between the second metallic plate 4_2 and the third metallic plate 4_3, etc. up to an N-th heater element 5 located between the N-th metallic plate 4_N and the (N+1)-th metallic plate 4_(N+1).

In one embodiment, each of the heater elements 5 may have a same pattern. In one embodiment, each of the (N+1) metallic plates 4 except the first metallic plate 4_1 and the last metallic plate (i.e., the (N+1)-th metallic plate 4_(N+1)) may have a same pattern. In one embodiment, the laterally alternating sequence of N+1) metallic plates 4 and N heater elements 5 may alternate along a first horizontal direction hd1. In one embodiment, each of the N heater elements 5 may have a strip portion 55 that laterally extends along a second horizontal direction hd2 that is perpendicular to the first horizontal direction hd1. In one embodiment, each strip portion 55 of the heater elements 5 may be located between a neighboring pair of metallic plates 4.

Each of the metallic plates 4 and the heater elements 5 may comprise a patterned portion of the at least one metallic material layer 50L. In one embodiment, each of the metallic plates 4 and the heater elements 5 may comprise a vertical stack of a metallic barrier plate 42 and a main metallic plate 44. Each metallic barrier plate 42 may be a patterned portion of the metallic barrier material layer 42L. Each main metallic plate 44 may be a patterned portion of the main metallic layer 44L. The etch mask layer may be subsequently removed, for example, by ashing.

According to an aspect of the present disclosure, the first metallic plate 4_1 may be electrically connected to an output node (such as a drain region 738) of the power amplifier 701, or to an input node (such as a gate electrode 754) of the low noise amplifier 702.

Each heater element 5 comprises a strip portion 55 having a narrow uniform width; a first terminal portion 52 adjoined to a first end of the strip portion 55; and a second terminal portion 58 adjoined to a second end of the strip portion 55 and laterally spaced from the first terminal portion 52. For example, the heater elements 5 may comprise the first heater element 5_1 located between the first metallic plate 4_1 and the second metallic plate 4_2, the second heater element 5_2 located between the second metallic plate 4_2 and the third metallic plate 4_3, etc. up to the N-th heater element 5_N located between the N-th metallic plate 4_N and the (N+1)-th metallic plate 4_(N+1). Generally, for each integer i that is greater than 0 and less than (N+1), the i-th heater element 5_i may be located between the i-th metallic plate 4_i and the (i+1)-th metallic plate 4_(i+1).

Each heater element 5 may comprise a strip portion 55 having a narrow uniform width; a first terminal portion 52 adjoined to a first end of the strip portion 55; and a second terminal portion 58 adjoined to a second end of the strip portion 55. In one embodiment, each strip portion 55 may have a narrow uniform width along a first horizontal direction hd1 and may laterally extend along a second horizontal direction hd2 that is perpendicular to the first horizontal direction hd1; and each second terminal portion 58 of a heater element 5 may laterally spaced from the first terminal portion 52 of the heater element 5 along the second horizontal direction hd2.

One of the first terminal portion 52 and the second terminal portion 58 of each heater element 5 may be connected to an output node of a programming transistor located within the semiconductor circuit 700 and configured to generate electrical current pulses for programming a first PCM switch to be subsequently formed, and another of the first terminal portion 52 and the second terminal portion 58 of each heater element 5 may be electrically grounded.

The uniform width of each strip portion 55 along the first horizontal direction may be a critical dimension, i.e., the smallest dimension that may be printed using a single lithographic exposure with the lithography tool used to pattern the etch mask layer (such as the patterned photoresist layer). For example, the uniform width of the strip portion 55 may be in a range from 10 nm to 60 nm, such as from 20 nm to 40 nm, although lesser and greater dimensions may also be used. The ratio of the length of the strip portion 55 to the width of the strip portion 55 may be in a range from 3 to 60, such as from 6 to 30, although lesser and greater ratios may also be used.

Each of the first terminal portion 52 and the second terminal portion 58 may comprise a pad region, which may have a shape of a rectangle or a rounded rectangle. Each pad region may be adjoined to the strip portion 55 by an intermediate region having a lesser width along the first horizontal direction hd1 than the pad region. Each intermediate region may have a shape of a rectangle or a trapezoid. Within each heater element 5, the first terminal portion 52 is adjoined to a first end of the strip portion 55, and the second terminal portion 58 is adjoined to a second end of the strip portion 55.

In one embodiment, each of the metallic plate 4 may have a rectangular shape. The width of each of the metallic plates 4 along the second horizontal direction hd2 may be in a range from 50% to 96%, such as from 70% to 90%, of the length of the strip portion 55 of each heater element 5 along the second horizontal direction hd2. The length of each of the metallic plates 4 along the first horizontal direction hd1 may be in a range from 50% to 300% of the width of the one of the metallic plates 4 along the second horizontal direction hd2, although lesser and greater lengths may also be used.

In one embodiment, the top surfaces of the heater elements 5 and the metallic plates 4 may be formed within a first horizontal plane. The bottom surface of the heater elements 5 and the metallic plates 4 may be formed within a second horizontal plane that includes the top surface of the via-level dielectric layer 24.

The width of the strip portion 55 of each heater element 5 along the first horizontal direction hd1 may be uniform throughout. In one embodiment, the width of the strip portion 55 of each heater element 5 along the first horizontal direction hd1 may be in a range from 10 nm to 100 nm, such as from 20 nm to 60 nm, although lesser and greater widths may also be used. The lateral separation distance between neighboring pairs of metallic plates among the metallic plates 4 may be in a range from 2 times the width of the strip portion 55 to 10 times the width of the strip portion 55, such as from 3 times the width of the strip portion 55 to 5 times the width of the strip portion 55. Each strip portion 55 is laterally spaced from neighboring metallic plates 4 by a gap.

Generally, at least one heater element 5 (which may be a plurality of heater elements 5) and metallic plates 4 may be formed over the first dielectric layers 600. Each of the at least one heater element 5 comprises a strip portion 55, a first terminal portion 52, and a second terminal portion 58. Top surfaces of the at least one heater element 5 and the metallic plates 4 may be coplanar, i.e., may be located within a same horizontal plane.

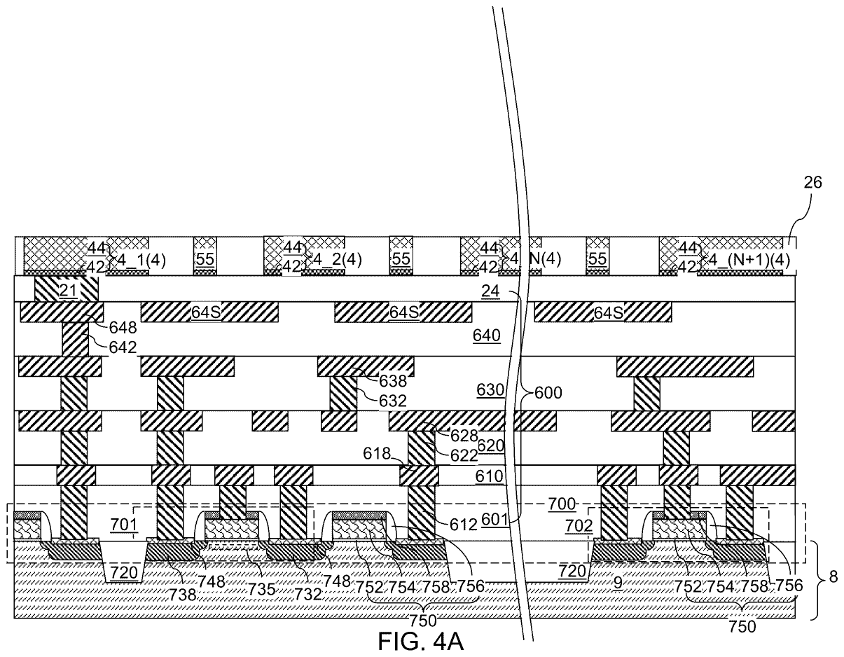

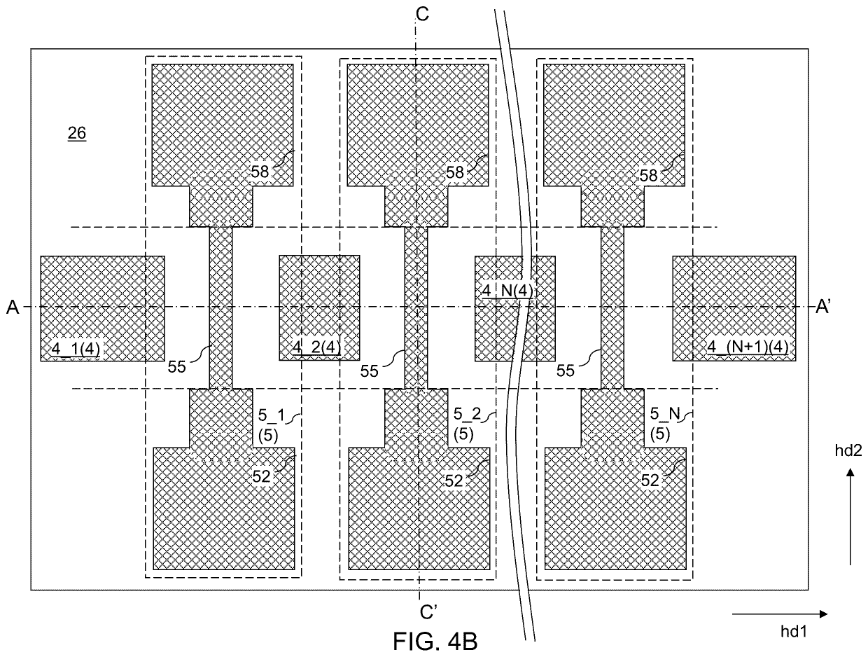

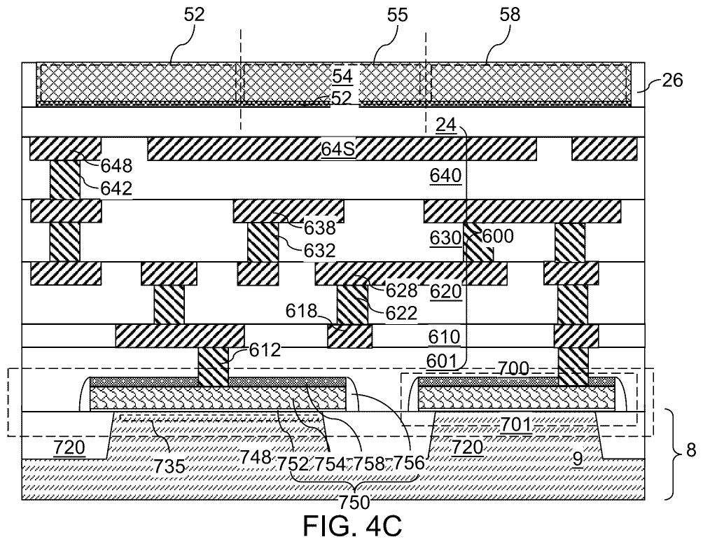

Referring to FIGS. 4A-4C, a dielectric material may be deposited over the various patterned portions of the at least one metallic material layer 50L, which includes the at least one heater element 5 (which may be a plurality of heater elements 5) and the metallic plates 4. The dielectric material comprises a planarizable dielectric material or a self-planarizing dielectric material. For example, the dielectric material may comprise undoped silicate glass having a dielectric constant of 3.9, a doped silicate glass having a dielectric constant in a range from 3.5 to 3.9, organosilicate glass having a dielectric constant in a range from 2.2 to 3.0, or nanoglass having a dielectric constant of about 1.3. Excess portions of the dielectric material may be removed from above the horizontal plane including the top surfaces of the heater elements 5, the first metallic plate 4_1, the second metallic plate 4_2, and the N-th metallic plate 4_N. Remaining portions of the dielectric material comprise a dielectric layer, which is herein referred to as an electrode-level dielectric layer 26. Top surfaces of the at least one heater element 5 and the metallic plates 4 may be coplanar with the top surface of the electrode-level dielectric layer 26.

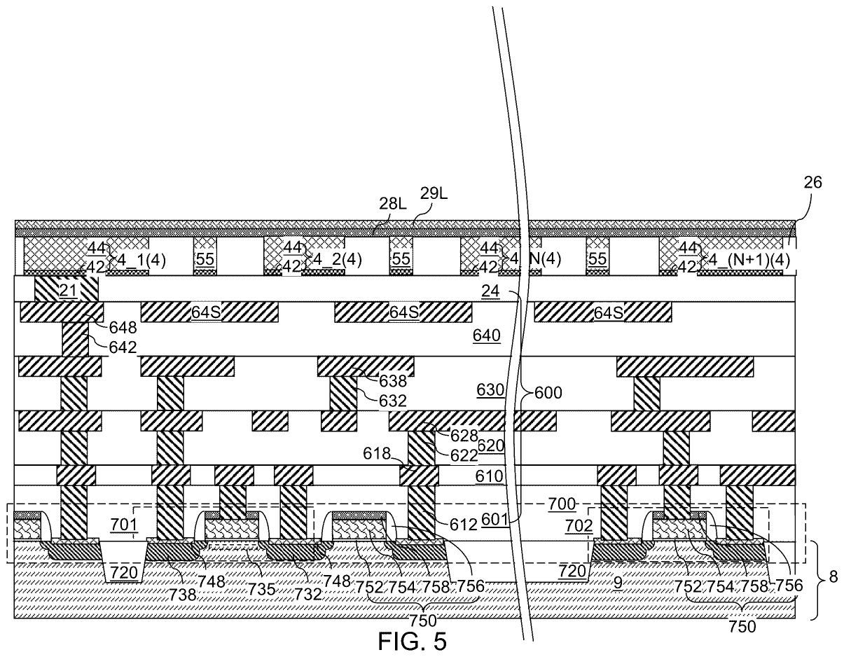

Referring to FIG. 5, a layer stack (28L, 29L) including an electrically-insulating and thermally-conductive layer 28L and a semiconducting material layer 29L may be formed over the at least one heater element 5, the metallic plates 4, and the electrode-level dielectric layer 26. The electrically-insulating and thermally-conductive layer 28L comprises a first material that may provide low electrical conductivity (i.e., high electrical resistivity) and high thermal conductivity. In one embodiment, the first material of the electrically-insulating and thermally-conductive layer 28L has an electrical resistivity in a range from 1.0×10¹⁰ Ohm·cm to 1.0×10¹⁵ Ohm·cm. In one embodiment, the first material of the electrically-insulating and thermally-conductive layer 28L has a thermal conductivity in a range from 10 W/m·K 2,300 W/m·K.

The first material may be selected among materials that provide electrical isolation while providing a reasonably high thermal conductivity to facilitate heat dissipation from the heater elements 5. In one embodiment, the first material of the electrically-insulating and thermally-conductive layer 28L comprises a material selected from aluminum nitride, silicon nitride, boron nitride, silicon carbide, and diamond. Aluminum nitride has thermal conductivity in a range from 140 W/m·K to 180 W/m·K. Silicon nitride has thermal conductivity in a range from 10 W/m·K to 30 W/m·K. Boron nitride, in its hexagonal form, has a thermal conductivity of approximately 600 W/m·K. Silicon carbide has thermal conductivity in a range from 120 W/m·K to 270 W/m·K. Diamond exhibits an exceptionally high thermal conductivity, ranging from 900 W/m·K to 2300 W/m·K. The electrically-insulating and thermally-conductive layer 28L may be deposited by chemical vapor deposition and may have a thickness in a range from 10 nm to 100 nm, such as from 20 nm to 70 nm, although lesser and greater thicknesses may also be used.

The second material of the semiconducting material layer 29L may have a lower electrical resistivity than the first material over the plurality of heater elements 5. In one embodiment, the second material of the semiconducting material layer 29L has an electrical resistivity in a range from 1.0×10⁻⁵ Ohm·cm to 1.0 Ohm·cm. The semiconducting material layer 29L may be deposited by chemical vapor deposition and may have a thickness in a range from 1 nm to 50 nm, such as from 2 nm to 10 nm, although lesser and greater thicknesses may also be used.

In one embodiment, the second material of the semiconducting material layer 29L comprises a metal oxide material selected from iridium oxide, zinc oxide, iron oxide, copper oxide, vanadium oxide, aluminum-doped zinc oxide, tin-doped indium oxide, and lithium-doped nickel oxide. Iridium oxide has an electrical resistivity typically ranging from 1.0×10⁻³ Ohm·cm to 1.0 Ohm·cm. Zinc oxide, depending on doping levels, may exhibit electrical resistivities as low as 1.0×10⁻⁵ Ohm·cm. Iron oxide, such as Fe₃O₄, has electrical resistivities typically ranging from 1.0×10⁻³ to 1.0×10⁻² Ohm·cm. Copper oxide has an electrical resistivity in the range from 1.0×10⁻² to 1.0×10⁻⁵ Ohm·cm. Vanadium dioxide (VO₂) exhibits electrical resistivities between 1.0×10⁻⁵ and 1.0×10⁻³ Ohm·cm in its metallic phase. Aluminum-doped zinc oxide typically has electrical resistivities in the range of 1.0×10⁻⁴ to 1.0×10⁻² Ohm·cm. Tin-doped indium oxide (ITO) has an electrical resistivity ranging from 1.0×10⁻⁴ to 1.0×10⁻² Ohm·cm, while lithium-doped nickel oxide may have electrical resistivities in the range of 1.0×10⁻³ to 1.0×10⁻² Ohm·cm.

In one embodiment, the second material of the semiconducting material layer 29L comprises a metallic nitride material selected from tantalum nitride, titanium nitride, tungsten nitride, and molybdenum nitride. Tantalum nitride (TaN) typically exhibits electrical resistivities between 1.5×10⁻⁴ Ohm·cm and 3.5×10⁻⁴ Ohm·cm. Titanium nitride (TiN) has electrical resistivity values ranging from 1.5×10⁻⁵ to 5.0×10⁻⁵ Ohm·cm. Tungsten nitride (WN) has electrical resistivities between 2.0×10⁻⁴ and 4.0×10⁻⁴ Ohm·cm, while molybdenum nitride (MoN) may exhibit electrical resistivities in the range of 1.0×10⁻⁴ to 2.5×10⁻⁴ Ohm·cm.

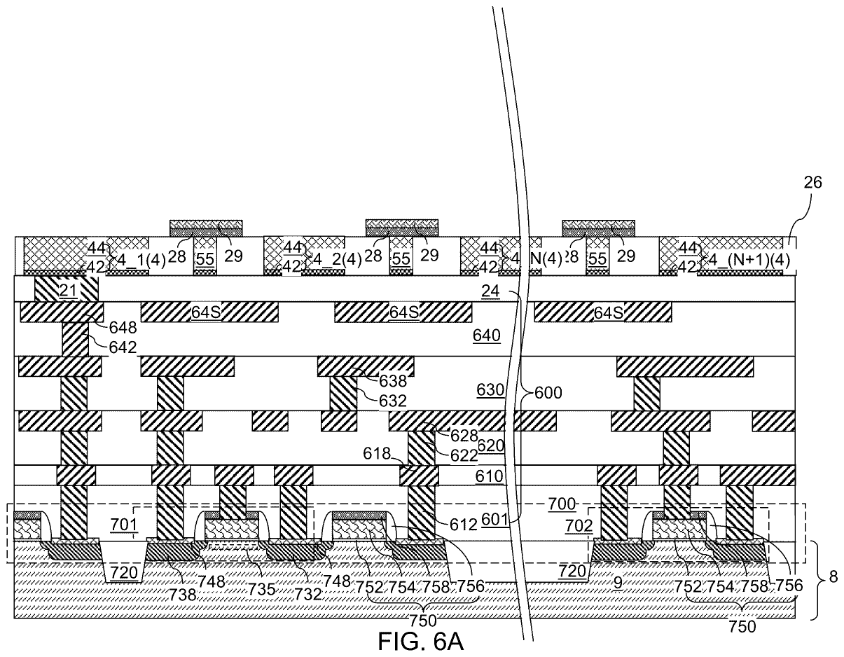

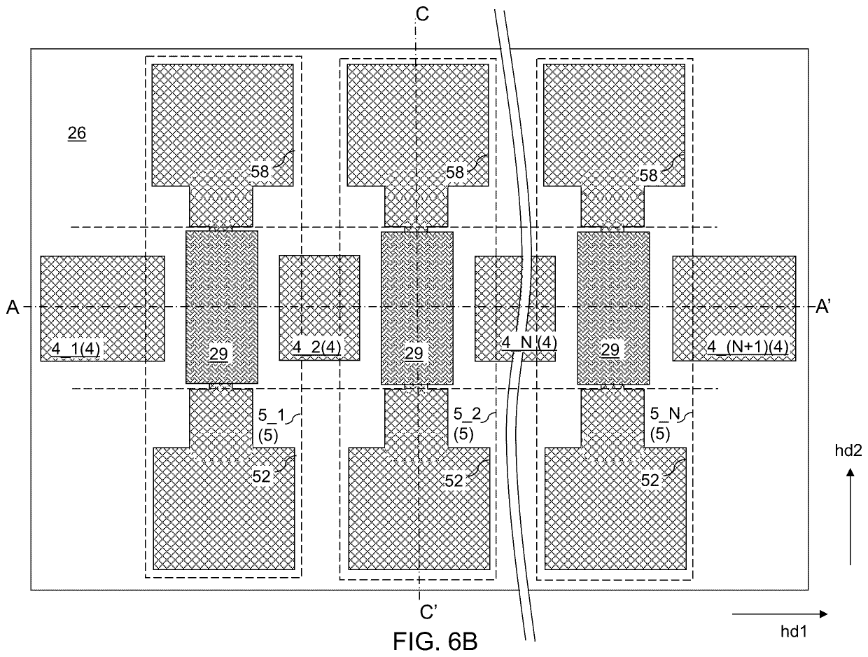

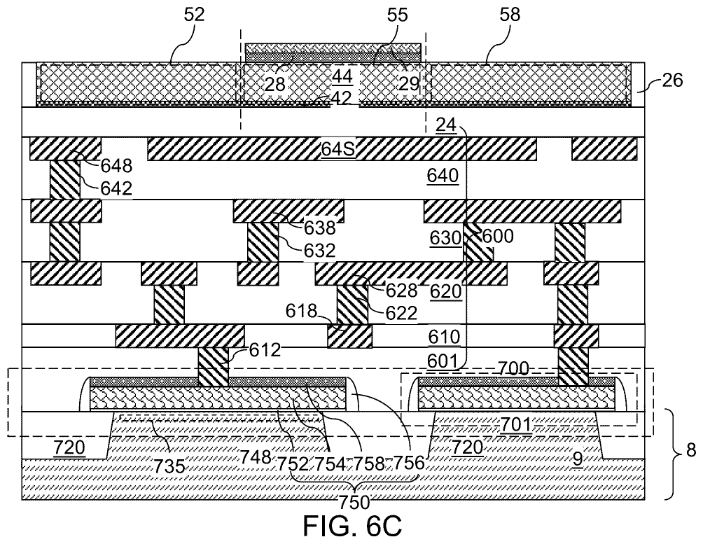

Referring to FIGS. 6A-6C, the layer stack (28L, 29L) may be patterned into at least one heater-cover plate stack (28, 29), which may comprise a plurality of heater-cover plate stacks (28, 29). For example, a photoresist layer (not shown) may be applied over the layer stack (28L, 29L), and may be lithographically patterned to form patterns that cover the strip portions 55 of the heater elements 5. Predominant portions (i.e., more than 50%) of the terminal portions (52, 58) of the heater elements 5 are not covered by the patterned photoresist layer. Further, the metallic plates 4 are not covered by the patterned photoresist layer.

An etch process may be performed to etch portions of the layer stack (28L, 29L) that are not masked by the photoresist layer. The etch process etches the unmasked portions of the layer stack (28L, 29L) selectively to the materials of the at least one heater element 5 and the metallic plates 4. The etch process may comprise an anisotropic etch process (such as a reactive ion etch process) or an isotropic etch process (such as a wet etch process). Patterned portions of the layer stack (28L, 29L) comprise at least one heater-cover plate stack (28, 29). The photoresist layer may be subsequently removed, for example, by ashing. Each heater-cover plate stack (28, 29) covers a strip portion 55 of a heater element. Each heater-cover plate stack (28, 29) includes a electrically-insulating and thermally-conductive plate 28 comprising a patterned portion of the first material, and further includes a semiconducting plate 29 comprising a patterned portion of the second material. In one embodiment, each heater-cover plate stack (28, 29) may have a first lateral dimension in a range from 300 nm to 2,200 nm along the first horizontal direction hd1, and may have a second lateral dimension in a range from 1.5 microns to 15 microns along the second horizontal direction hd2.

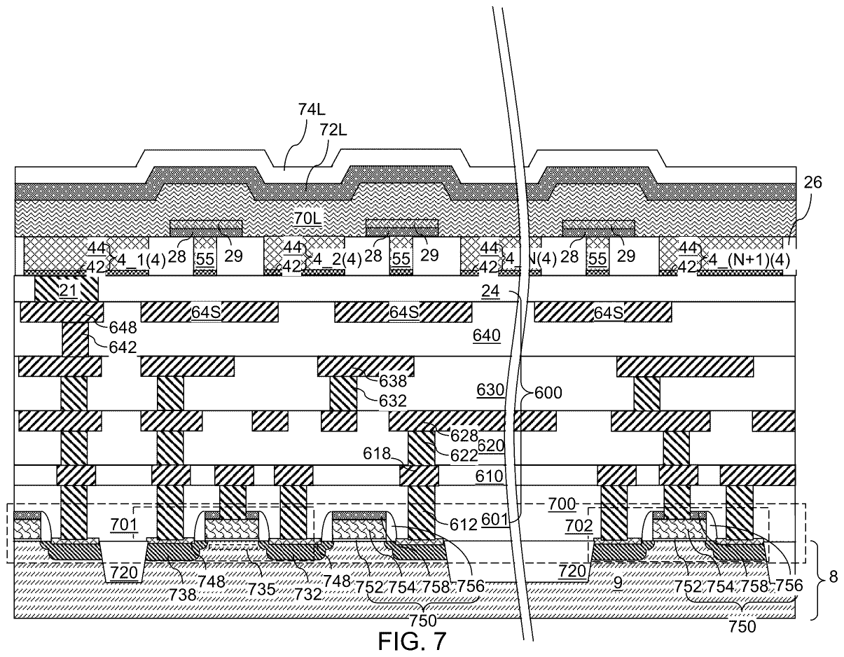

Referring to FIG. 7, a phase change material (PCM) layer 70L and at least one cover dielectric layer (72L, 74L) may be deposited over the at least one heater-cover plate stack (28, 29), the metallic plates 4, and the at least one heater element 5 (which may comprises a plurality of heater elements 5). The phase change material layer 70L may be deposited directly on the physically exposed top surface portions of the first metallic plate 4_1, the second metallic plate 4_2, the N-th metallic plate 4_N, and the heater elements 5.

The phase change material layer 70L comprises, and/or consists essentially of, a phase change material. As used herein, a “phase change material” refers to a material having at least two different phases providing different resistivity. A phase change material (PCM) may be used to store information as a resistivity state of a material that may be in different resistivity states corresponding to different phases of the material. The different phases may include an amorphous state having high resistivity and a crystalline state having low resistivity (i.e., a lower resistivity than in the amorphous state). The transition between the amorphous state and the crystalline state may be induced by controlling the rate of cooling after application of an electrical pulse that renders the phase change material amorphous in a first part of a programming process. The second part of the programming process includes control of the cooling rate of the phase change material. In embodiments in which rapid quenching occurs, the phase change material may cool into an amorphous high resistivity state. In embodiments in which slow cooling occurs, the phase change material may cool into a crystalline low resistivity state.

Exemplary phase change materials include, but are not limited to, chalcogenide-based compounds such as germanium antimony telluride (GST) compounds (e.g., Ge₂Sb₂Te₅, GeSb₂Te₄), germanium telluride compounds (e.g., GeₓTe_{γ}), antimony telluride compounds (e.g., SbₓTe_{γ}), and germanium antimony compounds (e.g., GeₓSb_{γ}). These materials may also be doped with elements such as silicon, nitrogen, oxygen, nickel, aluminum, titanium, tungsten, copper, carbon, boron, tin, indium, silver, and others to enhance resistance-switching characteristics. For example, doped phase change materials may include nitrogen-doped GST, Si-doped GeₓSb_{γ}Tez, or Ti-doped GeₓTe_{γ}. The phase change material may exhibit multiple phases with different resistivity levels, such as an amorphous state with high resistivity and a crystalline state with lower resistivity. The phase change material layer 70L may be deposited by physical vapor deposition. The thickness of the phase change material layer 70L may be in a range from 30 nm to 300 nm, such as from 70 nm to 120 nm, although lesser and greater thicknesses may also be used.

At least one cover dielectric layer (72L, 74L) may be deposited over the phase change material layer 70L. In one embodiment, the at least one cover dielectric layer (72L, 74L) may comprise a stack of a first cover dielectric layer 72L and a second cover dielectric layer 74L. In one embodiment, the first cover dielectric layer 72L may comprise a dielectric barrier material such as silicon nitride or silicon carbonitride, and the second cover dielectric layer 74L may comprise a dielectric material that is different from the dielectric barrier material. For example, the second cover dielectric layer 74L may comprise silicon oxide. The first cover dielectric layer 72L and the second cover dielectric layer 74L may be deposited by a chemical vapor deposition. The thickness of the first cover dielectric layer 72L may be in a range from 10 nm to 100 nm, such as from 20 nm to 60 nm, although lesser and greater thicknesses may also be used. The thickness of the second cover dielectric layer 74L may be in a range from 10 nm to 100 nm, such as from 20 nm to 60 nm, although lesser and greater thicknesses may also be used.

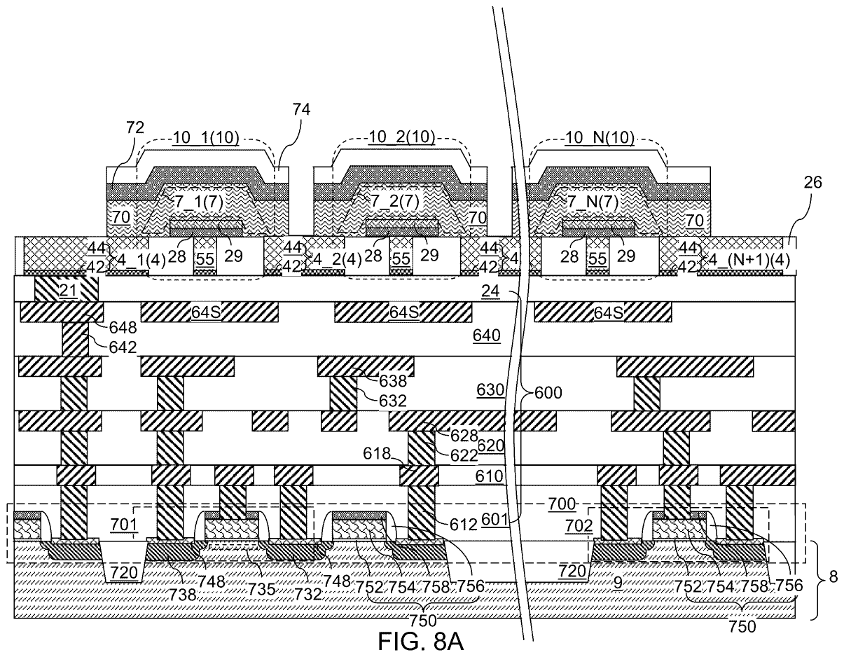

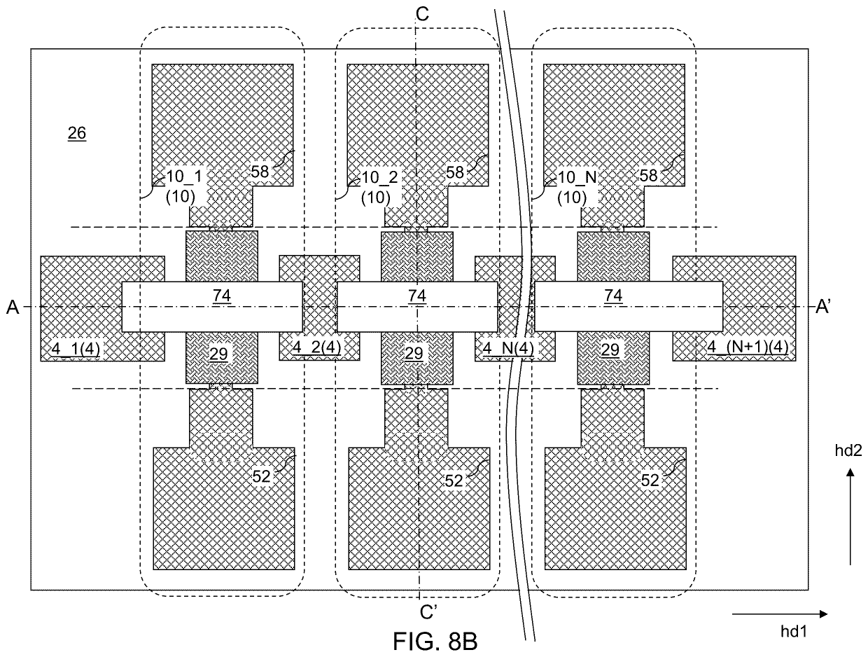

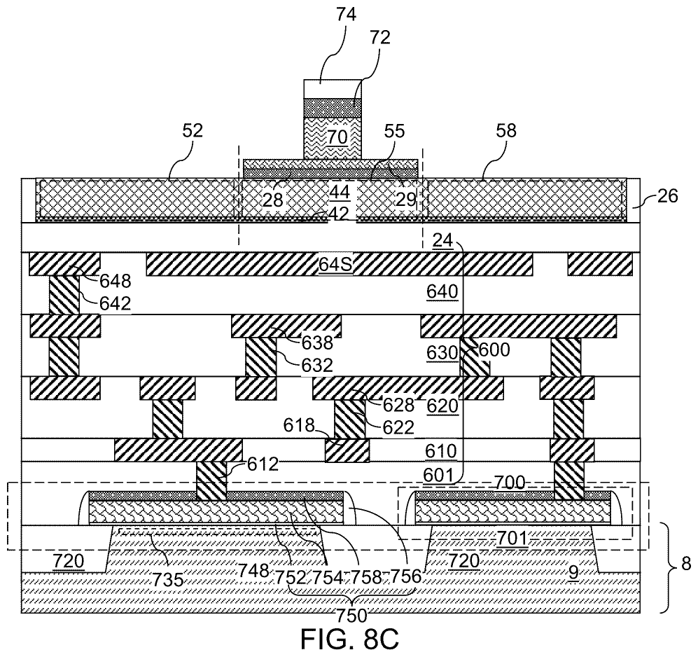

Referring to FIGS. 8A-8C, a patterned etch mask layer (not shown) may be formed over the at least one cover dielectric layer (72L, 74L). For example, a photoresist layer may be applied over the at least one cover dielectric layer (72L, 74L), and may be lithographically patterned to provide an elongated photoresist material portion that functions as the patterned etch mask portion 77. The patterned etch mask portion 77 straddles the strip portions 55 of each of the at least one heater element 5 and each of the metallic plates 4 along the first horizontal direction hd1. In one embodiment, the patterned etch mask portion may have a rectangular horizontal cross-sectional shape having lengthwise edges that are parallel to the first horizontal direction hd1 and having widthwise edges that are parallel to the second horizontal direction hd2.

Unmasked portions of at least one cover dielectric layer (72L, 74L) and the phase change material layer 70L may be etched by performing an anisotropic etch process that uses the patterned etch mask portion 77 as an etch mask. Thus, the anisotropic etch process etches portions of the at least one cover dielectric layer (72L, 74L) and the phase change material layer 70L that are not masked by the patterned etch mask portion 77. The patterned etch mask portion may be subsequently removed, for example, by ashing.

A remaining portion of the at least one cover dielectric layer (72L, 74L) comprises at least one cover dielectric plate (72, 74). In one embodiment, the at least one cover dielectric plate (72, 74) may comprise a stack of a first cover dielectric plate 72 and a second cover dielectric plate 74. The first cover dielectric plate 72 may comprise a patterned portion of the first cover dielectric layer 72L, and the second cover dielectric plate 74 may comprise a patterned portion of the second cover dielectric layer 74L.

Patterned portions of the phase change material layer 70L comprise at least one phase change material portion 70 that extends over a one of the at least one heater-cover plate stack (28, 29) and a pair of the metallic plates 4. In one embodiment, the total number of the heater-cover plate stacks (28, 29) may be N that is greater than 1, and the total number of the phase change material portions 70 may be N.

In one embodiment, the metallic plates 4, the plurality heater elements 5, and the phase change material portions 70 comprise a series connection of radio-frequency (RF) switches 10 in which a subset of metallic plates 4 are shared electrodes between a neighboring pair of RF switches 10 within the series connection of RF switches 10. In an illustrative example, the series connection of RF switches 10 may comprise a first RF switch 10_1 including the first metallic plate 4_1 and the second metallic plate 4_2 as conductive electrodes and including a first portion 7_1 of a first phase change material portion 70 as a first variable conductance channel; a second RF switch 10_2 including the second metallic plate 4_2 and the third metallic plate 4_3 as conductive electrodes and including a second portion 7_2 of a second phase change material portion 70 as a second variable conductance channel; etc. and an N-th RF switch 10_N including the N-th metallic plate 4_N and the (N+1)-th metallic plate 4_(N+1) as conductive electrodes and including an N-th portion 7_N of an N-th phase change material portion 70 as an N-th variable conductance channel. Generally, for each integer i greater than 0 and less than (N+1), an i-th RF switch 10_1 includes the i-th metallic plate 4_i and the (i+1)-th metallic plate 4_(i+1) as conductive electrodes and includes an i-th portion 7_i of the phase change material portions 70 as an i-th variable conductance channel.

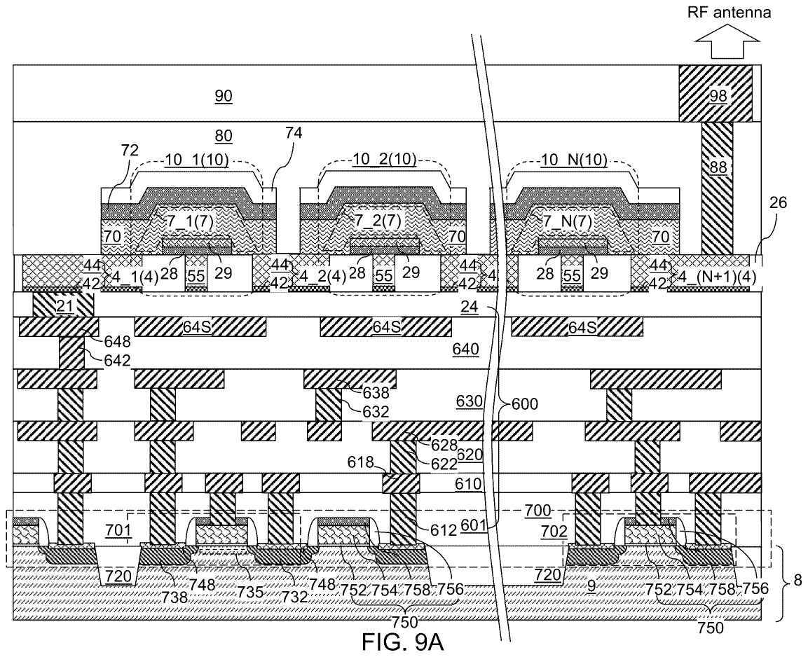

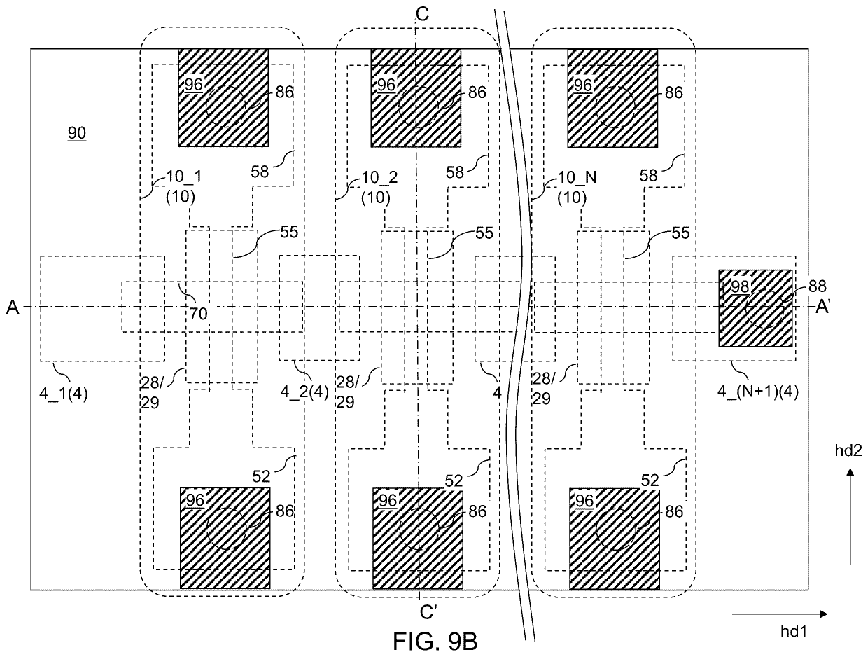

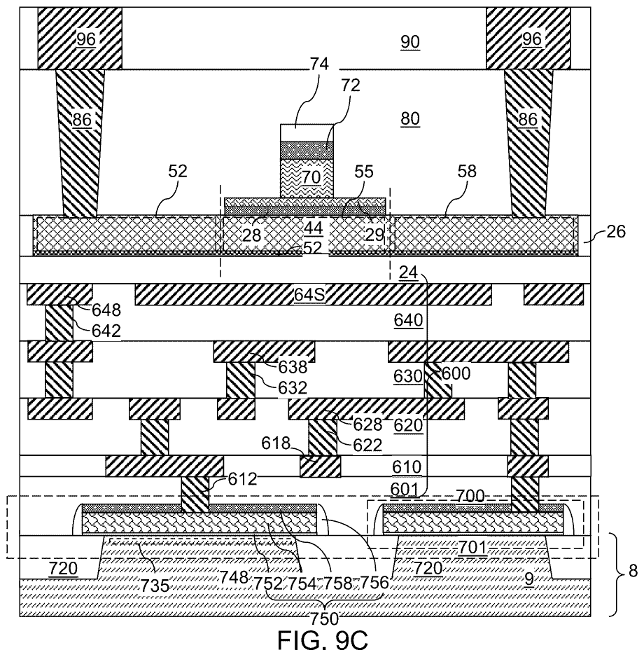

Referring to FIGS. 9A-9C, a PCM-level dielectric layer 80 may be deposited over the PCM switches 10. The PCM-level dielectric layer 80 comprises an interlayer dielectric (ILD) material such as undoped silicate glass, a doped silicate glass, porous or non-porous organosilicate glass, etc. The thickness of the PCM-level dielectric layer 80 may be in a range from 200 nm to 1,200 nm, although lesser and greater thicknesses may also be used. The PCM-level dielectric layer 80 is a bottommost layer among second dielectric layers that are formed over the series connection of the PCM switches 10.

A metallic via structure 88 may be formed through the PCM-level dielectric layer 80 directly on a top surface of the (N+1)-th metallic plate 4_(N+1), which constitutes an input electrode or an output electrode of the series connection of the N PCM switches 10. Heater electrode contact via structures 86 may be formed on each of the terminal portions (52, 58) of the heater elements 5.

Subsequently, additional second dielectric layers may be formed over the PCM-level dielectric layer 80. The additional second dielectric layers may comprise, for example, a line-level dielectric layer 90. A metal line structure 98 may be formed directly on a top surface of the metallic via structure 88 in the line-level dielectric layer 90. Further, additional metal line structures 96 may be formed directly on top surfaces of the heater electrode contact via structures 86. Each of the additional metal line structures 96 may be electrically connected to a one of the heater driver circuits within the semiconductor circuit 700 through a subset of the first metal interconnect structures (612, 618, 622, 628, 632, 638, 642, 648, 21, 64S).

Generally, second dielectric layers (80, 90) may be formed over the series connection of the PCM switches 10, and metallic via structures (88, 86) may be formed through a bottommost layer among the second dielectric layers (80, 90) directly on a top surface of the (N+1)-th metallic plate and the terminal portions (52, 58) of the heater elements 5.

A radio-frequency (RF) antenna may be electrically connected to the (N+1)-th metallic plate 4_(N+1) through the metallic via structure 88 and the metal line structure 98 by forming the RF antenna over the second dielectric layers (80, 90) or by attaching a structure (such an integrated passive device (IPD) die or an additional semiconductor die) including the RF antenna to an assembly containing the substrate 8, the first dielectric layers 600, and the second dielectric layers (80, 90).

The RF antenna may have any configuration known in the art. Examples of such configurations include microstrip antennas, planar inverted-F antennas (PIFA), spiral antennas, dipole antennas, and slot antennas. Each of these configurations exhibits distinct structural features suited for various applications. Microstrip antennas typically comprise a flat conductive strip (patch) positioned on top of a dielectric substrate with a ground plane on the opposite side, generally appearing as a rectangular or circular patch of metal, and are frequently utilized in wireless communication devices due to their simplicity and ease of integration. Planar inverted-F antennas (PIFA), a variant of the microstrip antenna, incorporate a shorting pin connecting the patch to the ground plane, appearing as a rectangular patch with a reduced dimension relative to its width and a shorting pin, making them prevalent in mobile phones and compact devices. Spiral antennas comprise a spiral-shaped conductor, manifesting as a circular or rectangular spiral pattern, and are used for wideband applications due to their extensive frequency response. Dipole antennas comprise two conductive elements (arms) aligned in a straight line, appearing as two straight metal lines extending from a central feed point, and are commonly used in fundamental RF applications. Slot antennas are manufactured by cutting a slot in a conductive plane, appearing as a rectangular or other shaped slot in a metallic surface, and are appropriate for integration with planar structures. These antenna configurations may be integrated into semiconductor dies utilizing advanced fabrication techniques to ensure precision and performance, thereby enhancing the functionality and efficiency of RF communication systems in various applications.

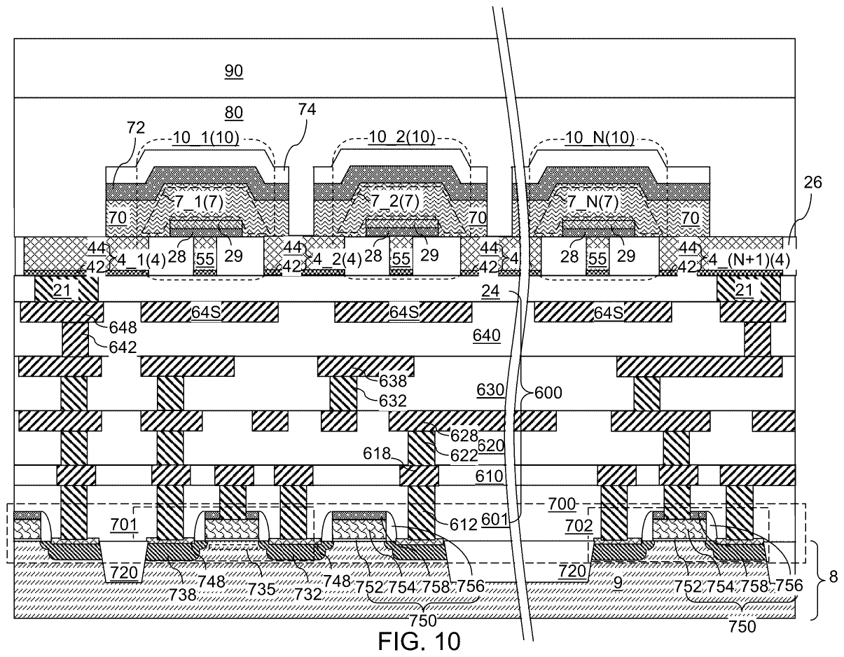

Referring to FIG. 10, an alternative configuration of the embodiment structure is illustrated. In the alternative configuration, the (N+1)-the metallic plate 4_(N+1) may be electrically connected to a node of an RF transistor circuit within the semiconductor circuit 700. The node of the first metallic plate 4_1 and the node of the (N+1)-th metallic plate 4_(N+1) constitute an input node and an output node of a series connection of N PCM switches 10.

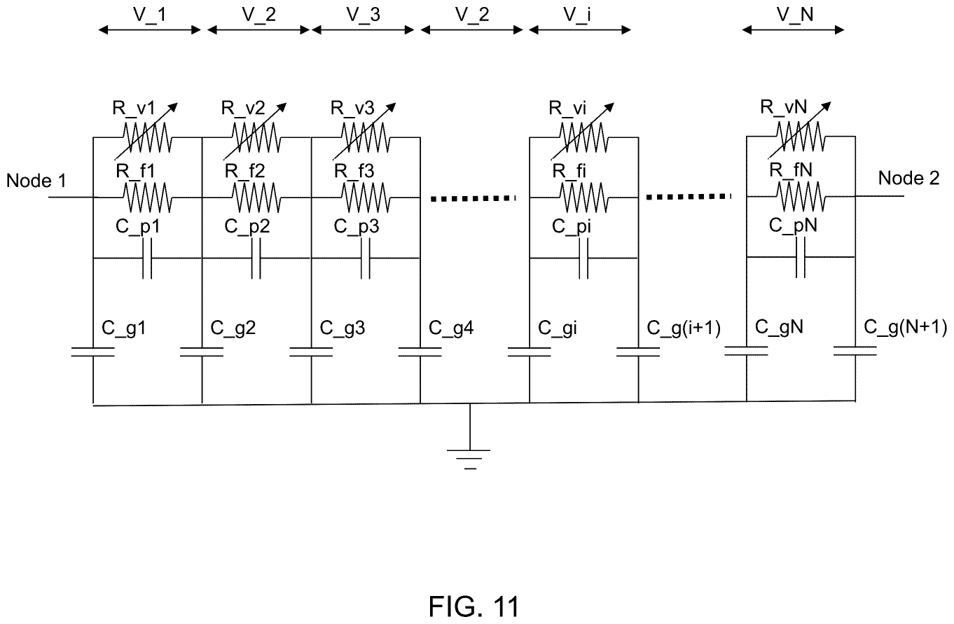

Referring to FIG. 11, a circuit diagram of the series connection of PCM switches 10 illustrated in FIGS. 9A-9C or in FIG. 10 is illustrated. The series connection of N PCM switches 10 comprises a first node (i.e., “Node 1”) and a second node (i.e., “Node 2”). The voltage between the first node and the second node is divided among the N PCM switches. For each integer i that is greater than 0 and less than (N+1), the voltage applied across an i-th PCM switch 10_i may be an i-th voltage V_i. Each i-th voltage V_i is determined by the set of all transconductance components across the metallic plates 4_i (1≤i≤(N+1)). For each integer i that is greater than 0 and less than (N+1), the transconductance components between the i-th metallic plate 4_i and the (i+1)-th metallic plate 4_(i+1) are determined by the variable resistance R_vi of the i-th portion 7_i of the i-th phase change material portion 70, the fixed resistance R_fi of the semiconducting plate 29 of the i-th heater-cover plate stack (28, 29), and the inter-electrode parasitic capacitance C_pi (which has a fixed value) between the i-th metallic plate 4_i and the (i+1)-th metallic plate 4_(i+1). In addition, for each integer i that is greater than 0 and less than (N+2), each i-th metallic plate 4_i has an i-th electrode-to-ground parasitic capacitance C_gi relative to the electrical ground.

While the series connection of the N PCM switches 10 is turned on, each variable resistance R_vi (1≤i≤(N+1)) may have a low value, and may be lower than any impedance generated from the fixed resistance R_fi of any semiconducting plate 29, from any inter-electrode parasitic capacitance C_pi, or from any electrode-to-ground parasitic capacitance C_gi, and may be lower than the output impedance or input impedance of the RF antenna or an RF transistor circuit to which the series connection of the N PCM switches 10 is connected. Thus, the sum of all voltages V_i is negligible. In other words, the voltage loss through the series connection of the N PCM switches 10 is negligible.

While the series connection of the N PCM switches 10 is turned off, each variable resistance R_vi (1≤i≤(N+1)) may have a high value which may differ among one another by orders of magnitude due to the variability of resistance of amorphous PCM material portions, i.e., among the various portions 7_i of the phase change material portions 70 that become amorphous. Thus, the voltage drop across each PCM switch 10 may be randomly distributed in the absence of the fixed resistance R_fi (1≤i≤(N+1)) of the semiconducting plates 29. The transconductance provided by the fixed resistance R_fi (1≤i≤(N+1)) is greater than the transconductance provided by the variable resistance R_vi (1≤i≤(N+1)), by the inter-electrode parasitic capacitance C_pi (1≤i≤(N+1)), or by the electrode-to-ground parasitic capacitance C_gi (1≤i≤(N+1)) by at least one order of magnitude. Each transconductance provided by the fixed resistance R_fi (1≤i≤(N+1)) may be substantially the same among one another because the semiconducting plates 29 have substantially the same shape. Thus, the voltages V_i (1≤i≤(N+1)) across each PCM switch 10 may be substantially the same, and the voltage differential across the first node and the second node may be evenly distributed across the N PCM switches 10. In other words, each V_i (1≤i≤(N+1)) may be substantially the same as the voltage difference between the first node and the second node divided by N. Thus, no PCM switch 10 is exposed to an excessively high voltage differential, and the reliability of the PCM switches 10 may be enhanced.

Referring collectively to FIGS. 1-11 and according to various embodiments of the present disclosure, a device structure is provided, which comprises: dielectric layers 600 having metal interconnect structures (612, 618, 622, 628, 632, 638, 642, 648, 21) formed therein; at least one heater element 5 located over the dielectric layers 600, each of the at least one heater element 5 comprising a strip portion 55, a first terminal portion 52, and a second terminal portion 58; at least one heater-cover plate stack (28, 29) located over a one of the at least one heater element 5, wherein each of the at least one heater-cover plate stack (28, 29) includes a electrically-insulating and thermally-conductive plate 28 comprising a first material and a semiconducting plate 29 comprising a second material having a lower electrical resistivity than the first material; and at least one phase change material portion 70 extending over the at least one heater-cover plate stack (28, 29).

In one embodiment, the device structure comprises metallic plates 4 overlying the dielectric layers 600, wherein each of the at least one heater element 5 is located between a neighboring pair of metallic plates 4 among the metallic plates 4. In one embodiment, the at least one heater element 5 comprises a plurality of heater elements 5 that are laterally spaced apart among one another; and the at least one phase change material portion 70 continuous extends over each of the plurality of heater elements 5. In one embodiment, the second material has an electrical resistivity in a range from 1.0×10−5 Ohm-cm to 1.0 Ohm-cm. In one embodiment, the first material has an electrical resistivity in a range from 1.0×10¹⁰ Ohm-cm to 1.0×10¹⁵ Ohm-cm.

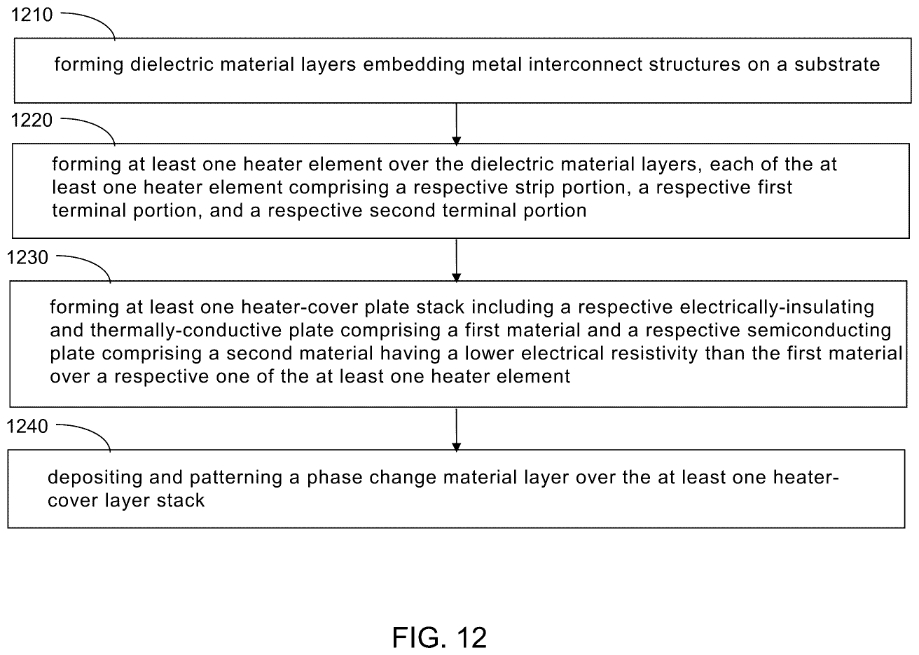

Referring to FIG. 12, a first flowchart illustrates general processing steps for manufacturing a device structure according to embodiments of the present disclosure.

Referring to step 1210 and FIG. 1, dielectric layers 600 having metal interconnect structures (612, 618, 622, 628, 632, 638, 642, 648, 21) formed therein may be formed on a substrate 8.

Referring to step 1220 and FIGS. 2A-3C, at least one heater element 5 may be formed over the dielectric layers 600. Each of the at least one heater element 5 comprising a strip portion 55, a first terminal portion 52, and a second terminal portion 58.

Referring to step 1230 and FIGS. 4A-6C, at least one heater-cover plate stack (28, 29) may be formed over a one of the at least one heater element 5. The at least one heater-cover plate stack (28, 29) includes an electrically-insulating and thermally-conductive plate 28 comprising a first material and a semiconducting plate 29 comprising a second material having a lower electrical resistivity than the first material.

Referring to step 1240 and FIGS. 7-11, a phase change material layer 70L may be deposited and patterned over the at least one heater-cover plate stack (28, 29).

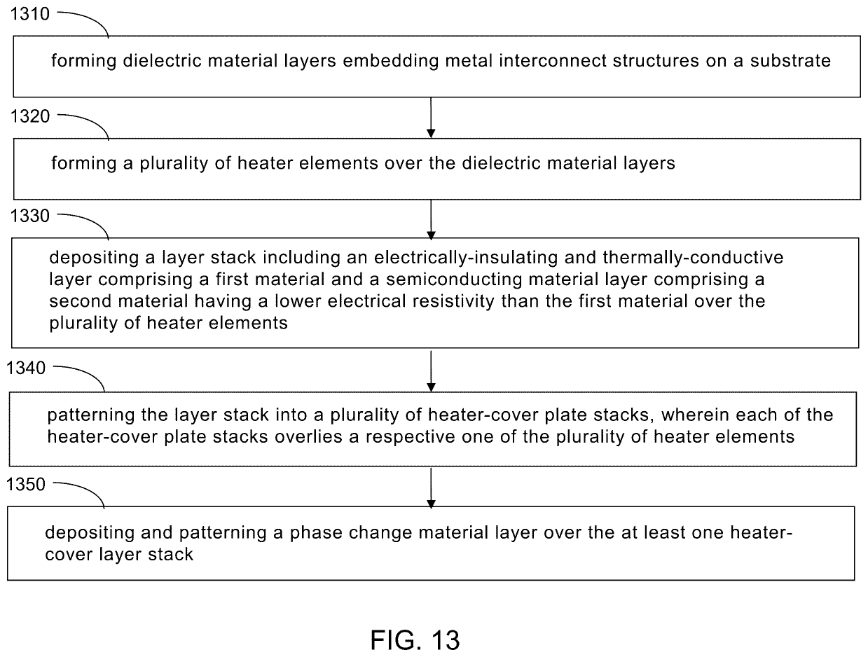

Referring to FIG. 13, a second flowchart illustrates general processing steps for manufacturing a device structure according to embodiments of the present disclosure.

Referring to step 1310 and FIG. 1, dielectric layers 600 having metal interconnect structures (612, 618, 622, 628, 632, 638, 642, 648, 21) formed therein may be formed on a substrate 8.

Referring to step 1320 and FIGS. 2A-3C, a plurality of heater elements 5 may be formed over the dielectric layers 600.

Referring to step 1330 and FIGS. 4A-5, a layer stack (28L, 29L) may be deposited, which includes an electrically-insulating and thermally-conductive layer 28L comprising a first material and a semiconducting material layer 29L comprising a second material having a lower electrical resistivity than the first material over the plurality of heater elements 5.

Referring to step 1340 and FIGS. 6A-6C, the layer stack (28L, 29L) may be patterned into a plurality of heater-cover plate stacks (28, 29). Each of the heater-cover plate stacks (28, 29) overlies a one of the plurality of heater elements 5.

Referring to step 1350 and FIGS. 7-11, a phase change material layer 70L may be deposited and patterned over the at least one heater-cover plate stack (28, 29).

Embodiments of the present disclosure address the issues of voltage imbalance and power handling limitations in stacked phase change material (PCM) RF switches, particularly in the off state, as discussed above. In related configurations, the uneven distribution of voltage across stacked PCM RF switches arises from the combination of parasitic capacitance to the substrate and variability in the off-state capacitance, which causes most of the input voltage to drop across the first device in the stack. This leads to device breakdown and limits the overall power handling capability, especially under high-power conditions.

The various embodiments disclosed herein mitigate these issues by incorporating off-state voltage equalizers, in the form of high-resistivity liner films, within the stacked PCM switch structure. These equalizers, represented as element R₁, are made of materials with resistivity lower than the amorphous phase change material (R_a) but higher than the crystalline phase change material (R_c), providing an additional current path. This configuration ensures that the voltage drop is more evenly distributed across all devices in the stack, as evidenced by the improved voltage balance (V_1=V_2= . . . =V_i= . . . =V_N) in the off state. By achieving this uniform voltage distribution, the risk of excessive voltage stress on any individual switch, particularly the first switch in the stack, is reduced. As a result, the stacked PCM switch structure may sustain higher input power levels without experiencing failure, thereby improving the overall off power handling capability of the device.

Furthermore, these embodiments offer additional advantages in thermal management by incorporating materials with high thermal conductivity, such as aluminum nitride or silicon nitride, in the heater-cover plate stacks. This ensures efficient heat dissipation, maintaining device reliability under elevated power conditions. Consequently, the methods and structures disclosed in the present embodiments provide a solution to the voltage imbalance and power handling challenges faced by prior PCM RF switch configurations, particularly in high-power RF applications.

The foregoing outlines features of several embodiments so that those skilled in the art may better understand the aspects of the present disclosure. Each embodiment described using the term “comprises” also inherently discloses that the term “comprises” may be replaced with “consists essentially of” or with the term “consists of” in some embodiments, unless expressly disclosed otherwise herein. Whenever two or more elements are listed as alternatives in a same paragraph or in different paragraphs, a Markush group including a listing of the two or more elements may also be impliedly disclosed. Whenever the auxiliary verb “can” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a device structure comprising:
forming dielectric layers with metal interconnect structures formed therein on a substrate;
forming at least one heater element over the dielectric layers, the at least one heater element comprising a strip portion, a first terminal portion, and a second terminal portion;
forming at least one heater-cover plate stack including:
an electrically-insulating and thermally-conductive plate comprising a first material; and
a semiconducting plate comprising a second material having a lower electrical resistivity than the first material over the at least one heater element; and
depositing and patterning a phase change material layer over the at least one heater-cover plate stack.

2. The method of claim 1, wherein the at least one heater-cover plate stack is formed by:
depositing a layer stack including a layer of the first material and a layer of the second material over the at least one heater element; and
patterning the layer stack, wherein patterned portions of the layer stack comprise the at least one heater-cover plate stack.

3. The method of claim 2, wherein the second material has an electrical resistivity in a range from 1.0×10⁻⁵ Ohm·cm to 1.0 Ohm·cm.

4. The method of claim 3, wherein the second material comprises a metal oxide material selected from iridium oxide, zinc oxide, iron oxide, copper oxide, vanadium oxide, aluminum-doped zinc oxide, tin-doped indium oxide, and lithium-doped nickel oxide.

5. The method of claim 3, wherein the second material comprises a metallic nitride material selected from tantalum nitride, titanium nitride, tungsten nitride, and molybdenum nitride.

6. The method of claim 2, wherein the first material has an electrical resistivity in a range from 1.0×10¹⁰ Ohm·cm to 1.0×10¹⁵ Ohm·cm.

7. The method of claim 2, wherein the first material has a thermal conductivity in a range from 10 W/m·K 2,300 W/m·K.

8. The method of claim 2, wherein the first material comprises a material selected from aluminum nitride, silicon nitride, boron nitride, silicon carbide, and diamond.

9. The method of claim 1, wherein a patterned portion of the phase change material layer comprises a phase change material portion extending over, and contacting each of, the at least one heater-cover plate stack.

10. The method of claim 9, wherein:
the at least one heater element comprises a plurality of heater elements that are laterally spaced apart among one another; and
the phase change material portion laterally extends over, and contacts, one of the plurality of heater elements.

11. A method of forming a device structure comprising:
forming dielectric layers with metal interconnect structures formed therein on a substrate;
forming a plurality of heater elements over the dielectric layers;
depositing a layer stack including an electrically-insulating and thermally-conductive layer comprising a first material and a semiconducting material layer comprising a second material having a lower electrical resistivity than the first material over the plurality of heater elements;
patterning the layer stack into a plurality of heater-cover plate stacks, wherein each of the plurality of heater-cover plate stacks overlies a one of the plurality of heater elements; and
depositing and patterning a phase change material layer over at least one of the plurality of heater-cover plate stacks.

12. The method of claim 11, wherein patterned portions of the phase change material layer comprises a plurality of phase change material portions that extends over the plurality of heater-cover plate stacks.

13. The method of claim 12, further comprising forming metallic plates formed within an electrode-level dielectric layer over the dielectric layers, wherein:
top surfaces of the metallic plates and top surfaces of the plurality of heater elements are coplanar with a top surface of the electrode-level dielectric layer; and
the layer stack is deposited over the electrode-level dielectric layer.

14. The method of claim 13, further comprising:
forming a semiconductor circuit including a radio-frequency (RF) transistor circuit comprising a power amplifier or a low noise amplifier on the substrate; and
providing an electrical connection with one of the metallic plates through a subset of the metal interconnect structures.

15. The method of claim 13, wherein the metallic plates, the plurality heater elements, and the plurality of phase change material portions comprise a series connection of radio-frequency (RF) switches in which a subset of metallic plates are shared electrodes between a neighboring pair of RF switches within the series connection of RF switches.

16. A device structure comprising:
dielectric layers having metal interconnect structures formed therein;
at least one heater element located over the dielectric layers, each of the at least one heater element comprising a strip portion, a first terminal portion, and a second terminal portion;
at least one heater-cover plate stack located over a one of the at least one heater element, wherein each of the at least one heater-cover plate stack includes a electrically-insulating and thermally-conductive plate comprising a first material and a semiconducting plate comprising a second material having a lower electrical resistivity than the first material; and
at least one phase change material portion extending over the at least one heater-cover plate stack.

17. The device structure of claim 16, further comprising metallic plates overlying the dielectric layers, wherein each of the at least one heater element is located between a neighboring pair of metallic plates among the metallic plates.

18. The device structure of claim 16, wherein:
the at least one heater element comprises a plurality of heater elements that are laterally spaced apart among one another; and
the at least one phase change material portion comprises a plurality of phase change material portions.

19. The device structure of claim 16, wherein the second material has an electrical resistivity in a range from 1.0×10⁻⁵ Ohm·cm to 1.0 Ohm·cm.

20. The device structure of claim 16, wherein the first material has an electrical resistivity in a range from 1.0×10¹⁰ Ohm·cm to 1.0×10¹⁵ Ohm·cm.
